(19) United States
(12) Patent Application Publication
(10) Pub. No.: US 2026/0047470 A1
(43) Pub. Date: Feb. 12, 2026

(54) NON-CONTINUOUS PAD STRUCTURE FOR POWER SEMICONDUCTOR DEVICES AND POWER SEMICONDUCTOR DEVICES INCLUDING NON-CONTINUOUS PAD STRUCTURES

(71) Applicant: Wolfspeed, Inc., Durham, NC (US)

(72) Inventors: Daniel Richter, Raleigh, NC (US); Thomas Harrington, Durham, NC (US)

(21) Appl. No.: 18/796,522

(22) Filed: Aug. 7, 2024

(51) Int. Cl. H01L 23/00; H01L 29/417; H01L 29/423

(52) U.S. Cl. CPC H01L 24/05; H01L 24/04; H01L 24/45; H01L 24/03; H01L 2224/0345; H01L 2224/04042; H01L 2224/05124; H01L 2224/05147; H01L 2224/05541; H01L 2224/05552; H01L 2224/05556; H01L 2224/05578; H01L 2224/05624; H01L 2224/05647; H01L 2224/05687; H01L 2224/06; H01L 2224/06131; H01L 2224/45124; H01L 2224/45147; H01L 2924/13091; H01L 2924/3511; H10D 64/252; H10D 64/258; H10D 64/512

(57) ABSTRACT

A semiconductor device according to some embodiments includes a semiconductor die, and a bond pad on a first side of the semiconductor die for receiving a wire bond. The bond pad includes a discontinuous uppermost surface opposite the first side of the semiconductor die.

### FIELD

The present disclosure relates to semiconductor power devices, and in particular to metallizations for power semiconductor devices.

### BACKGROUND

Power semiconductor devices typically have relatively thin topside and backside metallizations. This is the result of a number of factors, including metal deposition process capabilities, process time and cost, and stress induced warpage of the wafer. For high current power devices, however, these thin metallization layers introduce limitations to performance and reliability of the product. This is particularly so for wide band gap devices which offer considerably higher potential current densities. These higher densities require advancements in the devices and their associated packages to achieve their full potential.

The presence of thin layers may limit performance and reliability at both the device and package levels. For example, at the device level, thin metal layers may result in high current concentrations, uneven current distribution, localized heating and/or localized thermal stresses. At the package level, thin metal layers may result in limitations in the power interconnection size (wire diameter, ribbon thickness, etc.), limitations in the power interconnection material (softer materials vs. harder materials), a higher risk of device damage during wire/ribbon bonding, localized thermal stresses at the interconnection interface and/or limiting the allowable current (i.e. the device is not fully utilized).

Thicker metallization, particularly on the topside metal layer, may help address these issues on multiple fronts. For example, the use of thicker metallization (particularly top side metallization) may allow buffering the current to a more even distribution, and/or may reduce the localized heating and spreading it away from critical interfaces. Additionally, the use of thicker metallization may help to improve robustness for larger size power interconnections and/or may provide a capability to apply compatible materials for different power interconnection materials.

Creating the thicker metallization on a semiconductor wafer, however, has challenges which limit to what is practical and possible. Wafers are relatively thin at the time of processing, and may encounter multiple high temperature conditions as the devices are formed. Thicker metal layers, particularly if only on one side, can introduce warpage and distortion that are often too high for usage.

### SUMMARY

A semiconductor device according to some embodiments includes a semiconductor die, and a bond pad on a first side of the semiconductor die for receiving a wire bond. The bond pad includes a discontinuous uppermost surface opposite the first side of the semiconductor die.

The bond pad may include a plurality of separated pillars.

At least one of the plurality of separated pillars may have a width in a first direction that is less than a width of a footprint of the wire bond in the first direction.

The plurality of pillars may have a peripheral shape, when viewed from a direction opposite the semiconductor die, that is in a shape of a stripe, a circle, a polygon, and/or a ring.

The bond pad may include a continuous layer having a plurality of holes or openings therein.

The plurality of holes or openings may have a peripheral shape, when viewed from a direction opposite the semiconductor die, that is in a shape of a stripe, a circle, a polygon, and/or a ring.

The bond pad may be sized to receive a single wire bond.

The semiconductor may further include a bond wire that is bonded to the bond pad, wherein the bond wire contacts multiple ones of the plurality of pillars.

The bond pad may include a first metal layer on the semiconductor die, the first metal layer having a first thickness, and a second metal layer on the first metal layer, the second metal layer having a second thickness.

The first metal layer may include a continuous metal layer and the second metal layer may include a discontinuous metal layer.

The bond pad may include a source bond pad, an emitter bond pad, an anode bond pad, a gate bond pad, a kelvin bond pad, or a signal bond pad.

The pillars may be oriented in a pattern of rows and columns and/or in a pattern of diagonals, crosses and/or in a chevron pattern.

The bond pad may include copper, aluminum and/or aluminum-copper.

A semiconductor device according to some embodiments includes a semiconductor die, and a bond pad on a first side of the semiconductor die for receiving a wire bond. The bond pad includes a plurality of separated pillars opposite the semiconductor die that are configured to receive a wire bond. The plurality of separated pillars may form a discontinuous uppermost surface opposite the semiconductor die.

A semiconductor device according to some embodiments includes a semiconductor die, and a bond pad on a first side of the semiconductor die for receiving a wire bond. The bond pad includes a first metal layer on the semiconductor die and a second metal layer on the continuous metal layer. The second metal layer has a discontinuous uppermost surface opposite the semiconductor die.

The second metal layer may include a plurality of separated pillars opposite the semiconductor die. Upper surfaces of the plurality of separated pillars may form the discontinuous uppermost surface opposite the semiconductor die.

The second metal layer may include a plurality of holes or openings that extend partially through the second metal layer.

### BRIEF DESCRIPTION OF THE DRAWINGS

FIG. 1 illustrates an example of a MOSFET device.

FIG. 2 illustrates an example of a MOSFET circuit.

FIG. 3 illustrates a semiconductor device according to some embodiments.

FIGS. 4A and 4B, 5 and 6 illustrate metal stacks on a semiconductor device according to some embodiments.

FIG. 7 illustrates an example topside pattern for wire bonding in devices including a plurality of bond pads.

FIGS. 8A, 8B and 8C illustrate metal stacks for bond pads having discontinuous upper surfaces according to some embodiments.

FIG. 9 illustrates a conventional semiconductor device and a semiconductor device according to some embodiments.

FIG. 10 illustrates process steps that can be used to form bond pad according to some embodiments.

FIGS. 11-18 illustrate possible configurations of bond pads with pillars and holes according to various embodiments.

### DETAILED DESCRIPTION OF EMBODIMENTS

Wide Band Gap power devices, including devices based on silicon carbide (SIC), gallium nitride (GaN), and the like offer a high level of performance benefits, including high voltage blocking, low on-resistance, high current, fast switching, low switching losses, high junction temperatures, and high thermal conductivity. Ultimately, these characteristics result in a notable increase in potential power density, which is power processed per area or volume.

Achieving this potential, however, requires addressing significant challenges at the package and system level. The higher voltages, currents, and switching speeds manifest into significantly higher physical stresses applied onto smaller and more constrained areas. To fully take advantage of what SiC technology has to offer, several challenges must be addressed both at the device and the package level, including the formation of electrical interconnections from the device topsides to the package substrate or terminals. Other challenges include waste heat removal, including conduction and switching losses from the devices, and effective electrical isolation between high voltage potentials. Wide bandgap power devices should also have the capability to handle high steady state currents, capability to handle high transient current events, mechanical robustness to reliably operate in high stress, high temperature, high vibration environments. Such devices should be compatible with advanced interconnection materials, structures, and techniques, as well as with advanced device attach materials, structures, and techniques.

Power packages contain power semiconductor devices, including metal-oxide semiconductor field effect transistors (MOSFETs), junction field effect transistors (JFETs), insulated gate bipolar transistors (IGBTs), diodes, and the like, arranged into a variety of circuit topologies. A device package serves many functions, including electrical interconnection, electrical isolation, heat transfer, and mechanical structure. The package protects devices from environmental contamination and moisture, and provides external electrical and thermal connection interfaces. The package should also provide compliance with safety standards, such as voltage creepage and clearance distances.

Generally speaking, a semiconductor package can be a discrete package that houses a single device, or a power module that houses multiple devices. Power modules may place multiple devices in parallel and arrange them into various circuit topologies. As an example, a single switch position package that houses one device may be categorized a discrete package, and one that houses multiple devices in parallel (to increase output current) be considered a power module.

Packages conventionally use, but are not limited to, some combination of the following components, each providing multiple functions. These are summarized in the following table. The terms used in this disclosure, unless otherwise indicated, follow the definitions outlined in Table 1 below.

TABLE 1
Definitions

| Item | Description |
|---|---|
| Power Device(s) | Controllable switches MOSFET, IGBT, and the like, and Diodes |
| Substrate, Power | Layered metal and ceramic for high current electrical interconnection, |
| | high voltage isolation, high thermal conductivity, coefficient of thermal |
| | expansion (CTE) matching, and external thermal interface |
| Substrate, Signal | Layered Printed Circuit Board (PCB), layered metal and ceramic, thick |
| | film, and the like for high frequency electrical interconnection and high |
| | voltage isolation |
| Terminal, Power | Metal contact for high current external connection and internal |
| | interconnection |
| Terminal, Signal | Metal contact or connector for high frequency external connection and |
| | internal interconnection |
| Lead Frame | Metal contact strip for high current external connection and internal |
| | interconnection; Contacts are joined together on a single sheet, often |
| | with multiple products per sheet, and are processed as an array and then |
| | formed and singulated |
| Base Plate | Metal or composite material for mechanical structure, high thermal |
| | conductivity, coefficient of thermal expansion (CTE) matching, and |
| | external thermal interface |
| Device Attach | Solder, adhesive, or sintered metal, and the like for mechanical structure, |
| | high current interconnection, and high thermal conductivity |
| Terminal Attach | Solder, adhesive, sintered metal, laser weld, ultrasonic weld, and the like |
| | for mechanical structure, high current interconnection, and high thermal |
| | conductivity |
| Substrate Attach | Solder, adhesive, or sintered metal, and the like for mechanical structure |
| | and high thermal conductivity |
| Interconnection | Conductive element forming an electrical connection between one |
| | electrical node and another |
| Wire Bonds, Power | Ultrasonically or thermosonically bonded large diameter wire, ribbon, |
| | and the like for high current electrical interconnection |
| Wire Bonds, Signal | Ultrasonically or thermosonically bonded small diameter wire, ribbon, |
| | and the like for low current electrical interconnection |
| Case / Housing | Injection molded case and lid, providing mechanical structure, high |
| | voltage isolation, and acting as a well for the encapsulation material |
| Mold Compound | Transfer or compression molded epoxy molding compound (EMC) for |
| | mechanical structure, high voltage isolation, coefficient of thermal |
| | expansion (CTE) matching, and low humidity absorption |
| Encapsulation | Soft, flexible silicone or similar encapsulation material for high voltage |
| | isolation, and low humidity absorption |
| Temperature Sensor | Passive or active element that can be used to monitor internal |
| | temperatures |
| Signal Circuitry | Resistors, capacitors, surface mount components, sensors, and the like |
| | for stabilization of the dynamic switching performance of the devices or |
| | for other internal circuit requirements, such as active miller clamping, |
| | etc. |

Some typical design requirements for power device packages include high power density (small package size), high current, high voltage, high temperature operation, low thermal resistance, low stray inductance, fast and clean switching, high efficiency through low on-resistance, high efficiency through high speed switching, thoughtful external terminal layout for effective interconnection, compliance with creepage and clearance standards, moisture sensitivity level (MSL) compliance, and low cost.

A power semiconductor device is typically vertical, meaning power flows from top the backside to the topside of the chip (or vice versa). While there are many types of power devices where this technique applies, a MOSFET will be used for the purposes of explanation and illustration.

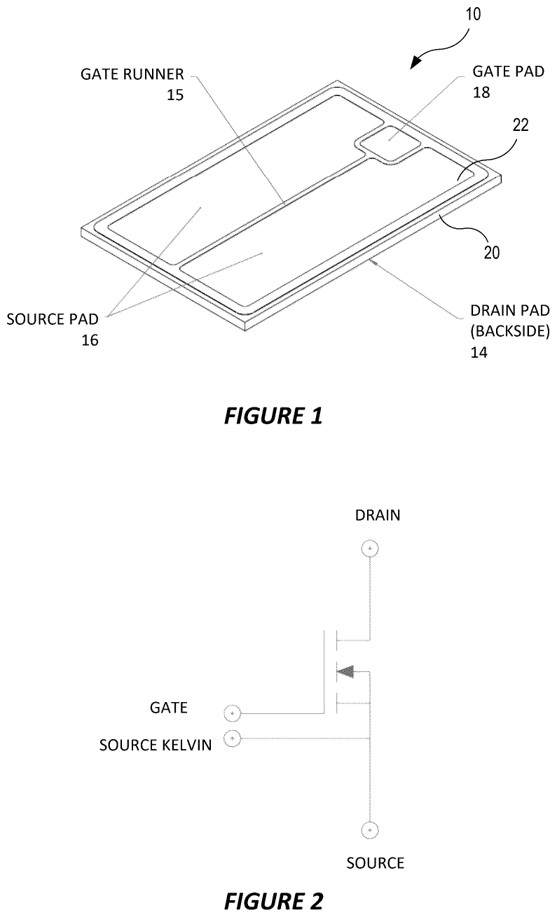

A power MOSFET is a three-terminal device: (1) gate, (2) source, and (3) drain. Often an additional kelvin connection to the source terminal is made to optimize switching performance to isolate the power and signal loops. The gate and source are located on what will be referred to as the device topside, while the drain is located on the device backside. The high current path flows from the drain to source or source to drain, through the area of the device. An example MOSFET device is depicted in FIG. 1, and an example MOSFET circuit element is depicted in FIG. 2.

Referring to FIGS. 1 and 2, a MOSFET device 10 generally includes source, gate and drain terminals. The source terminal is connected to a pair of source pads 16 on the front or top side of a semiconductor die 20, and the gate terminal is connected to a gate pad 18 on the front or top side of the die 20. A gate runner 15 extends from the gate pad 18 and distributes the gate signal across the die 20. The drain terminal is connected to a drain pad 14 on the back side of the die 20.

The topside metallization 22 that forms the source pads 16 and the gate pad 18, as well as the backside metallization that forms the drain pad 14, generally include stack of metals to provide a variety of functions, such as ohmic contact, diffusion barrier, seed layers for plating or adhesion, and a capping bonding layer. The topside bonding layer is generally the thickest and is designed to be metallurgically compatible with the desired topside interconnection method. For example, the topside bonding layer may be aluminum to be most compatible with aluminum wire bonding or copper to be compatible with copper wire bonding. The backside metallization is also a stack of metals serving similar functions. Backside attaches tend to be a soldered, brazed, or sintered, rather than connected to wire bonds. The thickness of each layer is generally selected based on what is practical and cost effective to fabricate, what operating conditions are expected, and what performance requirements must be met.

While a power semiconductor device operates as a single device, the physical chip layout is a large array of paralleled device ‘cells’ interconnected through the topside metallization and other functional layers.

In many cases, only a portion of the source pad 16 can be used for interconnection through wire bonds or ribbons. Hence, current must spread from these sites out towards the device cells. To effectively obtain the most performance out of the device 10, each of these device cells should be fully utilized by carrying as much current as possible. Accordingly, distributing the current from the interconnection sites to each and every cell is important for full device utilization. Distributing current equally among the cells also helps to spread heat evenly across the device.

Using thicker metal may reduce the sheet resistance of the topside metallization 22, and may provide more cross sectional area through which current can readily spread. Increasing the thickness of the topside metallization layer 22 may allow for more cells to access a low resistance, efficient path to the input and output sites for current flow. This buffering effect may reduce high current concentrations and/or may reduce localized heating at the bonding interfaces.

With a thin metallization, there is limited room to laterally spread current and the resulting heat at the interface. These localized high current and heat densities can act to stress and weaken the interface. A thicker metallization helps to buffer the current and heat to better distribute the energy away from the interfaces and evenly towards the device cells.

The application of a thicker topside metal may also improve device robustness for more aggressive interconnection methods. For example, copper wire is substantially harder than aluminum, and could cause damage to the sensitive device during the wire bonding process. Thicker metals can buffer out the energy applied to form the metallurgical bonds, and a ‘cushioning’ effect adding resilience and wider process windows. Thus, it may be preferable for the thicker topside metal to improve the performance and bondability of copper wires. Moreover, due to the high conductivity of copper, the use of copper in the topside metal can enable the use of fewer wire bonds, or may allow higher currents for a given number of wire bonds. The use of thick topside metal may also accommodate larger wire bond footprints, which can allow for more current.

While there are numerous benefits to thicker metallization layers, there are also many processing challenges. For example, there is a large coefficient of thermal expansion (CTE) imbalance between the semiconductor wafer and the metal layers. As the wafer is exposed to high temperatures during processing, the metal and semiconductor expand and contract at different rates, creating thermal stress. These thermal stresses can manifest as warpage of the wafer once cooled. A wafer can also experience residual stress (sometimes called intrinsic stress) from the copper electroplating process. Stress in the copper is not derived from a high temperature process, but from the plating itself (typically done at room or a bit higher). This is dependent on the plating chemistries and electroplating conditions used and the thickness of copper being plated.

Warpage is a major problem which may reduce yield or render the wafer useless for further processing. Depending on the temperature delta, metal layout, wafer thickness and diameter, and other factors, a warped wafer could be convex, concave, or bimodal (concavo-convex). The risk of warpage exceeding a usable level increases as the metal thickness increases. This is particularly so if it is only increased on one side of the device.

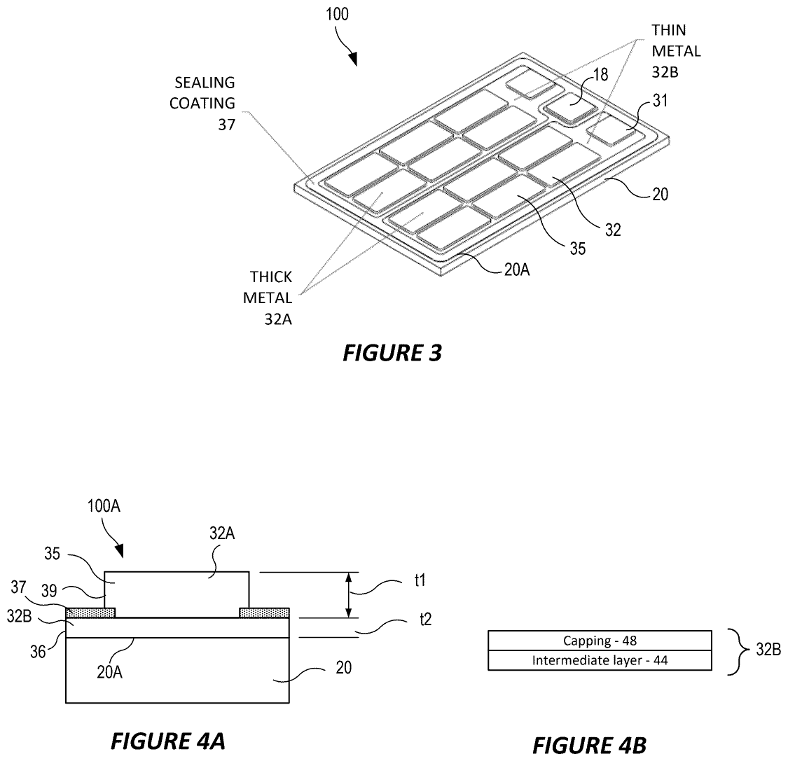

To address the issue of wafer warpage while delivering the benefits of thick metallization, some approaches apply thick metal selectively using multiple masked deposition processes. That is, instead of applying thick metal on all conductive surfaces, the thick metal is applied selectively only where it is needed. These localized thick plateaus of metal provide buffering and robustness but are small enough that the metal loading is greatly reduced, and the expansion stresses are lessened. This approach is shown on an example power device in FIGS. 3, 4A and 4B. A section view is also presented. Note that there are many functional layers in the sectional view that are not shown for simplicity. Embodiments are described herein in the context of MOSFET power semiconductor devices. However, it will be appreciated that the inventive concepts may be applied to many different types of semiconductor devices, such as JFETs, IGBTs, diodes, and other devices.

Referring to FIGS. 3, 4A and 4B, a semiconductor MOSFET device 100A according to some embodiments includes a semiconductor die 20 on which a topside metallization 32 is formed on an upper surface 20A of the semiconductor die 20. The top side metallization 32 includes a thin metal layer 32B formed on an upper surface 20A of the die 20, and a thick metal layer 32A formed on the thin metal layer 32B. The thin metal layer 32B and the thick metal layer 32A may together form, for example, a source contact of the semiconductor device 100A. As used herein in reference to metal layers, the terms “thick” and “thin” refer to the dimension of the metal layer as measured in a direction normal to the surface on which the metal layer is formed, such as the upper surface 20A of the semiconductor die 20. Thus, for example, the thick metal layer 32A has a thickness t1, while the thin metal layer 32B has a thickness t2 as illustrated in FIG. 4A.

Referring still to FIGS. 3, 4A and 4B, a sealing coating (or sealing layer) 37 may be formed on portions of the upper surface 20A of the die 20 not covered by the thick metal layer 32A. The sealing coating 37 may be a material, such as polyimide, that blocks the diffusion of metals. Other materials that block metal diffusion, such as TiN, TaN, etc., may also be used as or in conjunction with the sealing coating 37.

The thick metal layer 32A may include a metal, such as copper or aluminum, that is suitable for connection by a wire bond (not shown). The thick metal layer 32B is formed as a plurality of discrete thick metal regions on the thin metal layer 32A. The discrete thick metal regions may serve as bond pads 35 of the device 100A. That is, the bond pads 35 are physically separated from one another and are mechanically and electrically connected to one another only through the thin metal layer 32B. The bond pads 35 include a plurality of source wire bond pads, or source bond pads. The bond pads 35 also include a source kelvin bond pad 31 to facilitate a source kelvin connection to the device input signal line as shown in FIG. 2.

The thick metal layer 32A is formed where needed for a desired performance, interconnection scheme, and interconnection material. It may be deposited through similar processes as the thin metal layer 32B. A mask or similar may be used to only apply the metal where desired to form the bond pads 35. The bond pads 35 may also be formed by plating a thick layer of metal over the thin metal layer 32B and etching or selectively depositing the plated metal to form the bond pads 35. Plating is a practical and cost effective to form relatively thick layers.

The thin metal layer 32B may have a thickness of about 1 micron to 5 microns, while the thick metal layer 32A may have a thickness of about 20 microns or more. In some embodiments, the thick metal layer 32A may have a thickness that is at least 1.5 times the thickness of the thin metal layer. In further embodiments, the thick metal layer 32A may have a thickness that is at least 2 times the thickness of the thin metal layer. In still further embodiments, the thick metal layer 32A may have a thickness that is at least 5 times the thickness of the thin metal layer. In still further embodiments, the thick metal layer 32A may have a thickness that is at least 10 times the thickness of the thin metal layer. In still further embodiments, the thick metal layer 32A may have a thickness that is at least 20 times the thickness of the thin metal layer.

By forming a thin layer of metal on the semiconductor die 20, the design rule for manufacturing the semiconductor die 20 may be tightened, which means that it may be possible to form smaller or more dense features in the semiconductor die 20 than would be possible if only a single thick metal stack were formed thereon. It will be appreciated that the design rule for a semiconductor die determines how closely or densely features can be formed on the die. When the initial metal layer on the die is thick, a larger design rule is required due to lateral variations in the thick metal layer to discourage the initial metal layer from undesirably contacting unintended features on the die. According to some embodiments, by forming an initial metal layer as a thin layer 32B having a thickness of less than 5 microns, the design rule for the semiconductor die may be reduced.

As seen in FIG. 4A, the thick metal layer 32A may be formed so that the side walls of the bond pads 35 are inwardly recessed from the sidewalls of the thin metal layer 32B. That is, the outside edges 39 of the bond pads 35 may not reach all the way to the outside edges 36 of the thin metal layer 32B. As used herein with respect to metal layers, the term “edge” refers to the outer sidewall, outer surface or outer portion of the metal layer.

Referring to FIG. 4B, the thin metal layer 32B may be part of a first layer metal stack which typically includes a capping metal 48 and one or more intermediate layers 44 between the capping layer 48 and the semiconductor die 20. These layers may be deposited through a number of processes, including but not limited to evaporation, sputtering, plating, and the like.

The capping layer 48 may be a metal that is metallurgically compatible with the desired material for the thick metal layer 32A, which typically includes copper but may include aluminum. For example, the capping layer 48 may include copper, aluminum copper, aluminum, or any other suitable metal.

The thick metal layer 32A may include a material with a high mechanical strength. Generally, copper may be desirable to use for the thick metal layer 32A, due to its mechanical strength and/or hardness, to support the formation of copper wire bonds to the bond pads 35. The force of forming a wire bond to the bond pad 35 may displace softer metals, such as aluminum, pushing it to undesired locations on the die.

Copper is also desirable for use as the thick metal layer 32A due to its high electrical and thermal conductivity. However, in some cases other metals may be desirable. The thick metal layer 32A may be left bare, or in some cases it may be further plated with a more oxidation resistant material such as nickel, palladium, gold, etc., or in other cases a second sealing layer such as a second polyimide layer may be deposited and patterned to protect or contain the edges of thick metal layer 32A.

The intermediate layer 44 may include a diffusion barrier layer which serves the purpose of obstructing inter-diffusion of soluble metals. As an example, if the capping layer 48 contains copper, then without a diffusion barrier, copper may spread into and contaminate the underlying metals and also likely diffuse into the underlying insulating layers, interconnects, gate oxides, and substrate of the die 20. This ultimately may inhibit or destroy the function of the device 100A. Adding an insoluble diffusion barrier layer of, for example, TiN may obstruct this from occurring. The intermediate layer may include other layers, such as adhesion layers, seed layers, etc.

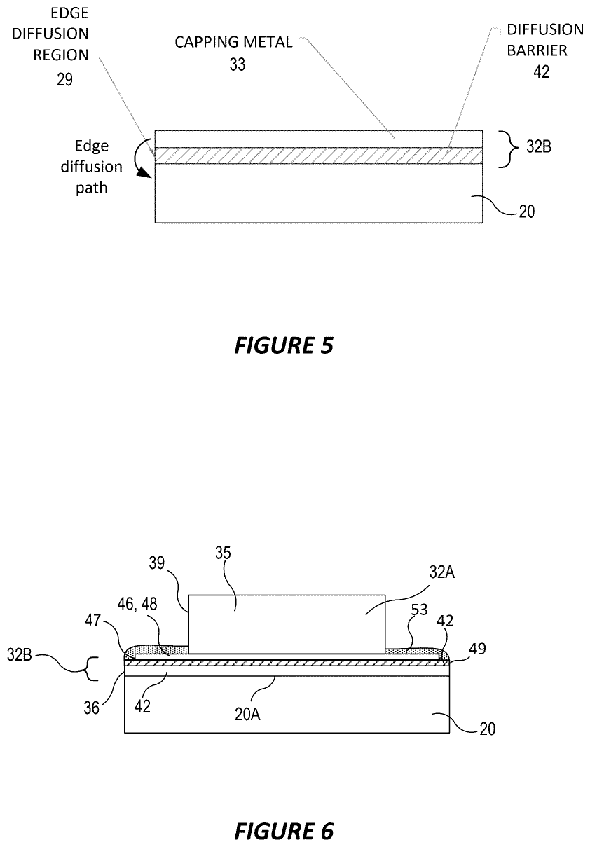

Even if a diffusion barrier is used, however, diffusion may still be possible at the edges of the interface. That is, metal can diffuse around the edges where there is no diffusion barrier in the vertical direction. This is illustrated in FIG. 5, which shows a capping layer with regions 29 where edge diffusion could occur (left) from a capping layer 33 to the die 20.

FIG. 6 illustrates a selective approach in which the seed layer 46 and capping layer 48 are inset from the outer edges of the diffusion barrier layer 42. That is, outer edges 47 of the seed layer 46 and capping layer 48 do not extend all the way to the outer edge 49 of the diffusion barrier layer 42. This may reduce the possibility of edge diffusion from the seed and copper layers 46, 48 into the die 20.

A sealing layer 53 is provided over the seed layer 46 and capping layer 48. The sealing layer 53 encapsulates the stepped edge 47 and extends to the outer edge 39 of the bond pad 35. If the sealing layer 53 was not present, the capping metal 33 would diffuse out from the outer edge 47, over the outer edge 49 and down into the semiconductor. The sealing layer 53 may be polyimide or another encapsulant-type coating. However, the sealing layer 53 may be any layer that provides a barrier to metallic diffusion, such as TIN, TaN, etc. The sealing layer 53 is typically not an oxide layer (like SiO2) since oxide layers do not prevent metallic diffusion.

Moreover, the bond pad 35 of the thick metal layer 32A is inset such that the outer edge 49 of the diffusion barrier layer 42 extends past the outer edge 39 of the bond pad 35 to further reduce the possibility of edge diffusion from the bond pad 35.

There are many implementations of topside metallization using the selective metal approach according to various embodiments of the inventive concepts. The specific approach could be tailored to accommodate a number of factors, including one or more of device size, device aspect ratio, device shape, pad size, interconnection method, interconnection material, bonding direction, bonding pattern, package features and/or product application.

Example topside features are described in the following for a reference device. These may be used by themselves or in combination with backside features depending on many of the factors listed above. Interconnection in the examples includes signal and power bonds. Individual interconnection bonds for each thick pad are illustrated. However, the pads may be stitch bonded together as well, which is not pictured but is also possible with this method.

Note that a specific implementation is not limited to these examples, and ultimately is driven by product and application factors. Also note that there is an unused bond pad in the examples (on the upper left side) that could be used as an alternative site for source kelvin bonding. It could also be used as a bonding site for on-chip sensors like temperature, current, and the like. Additional bonding pads would be configured to match the specific needs of that particular device.

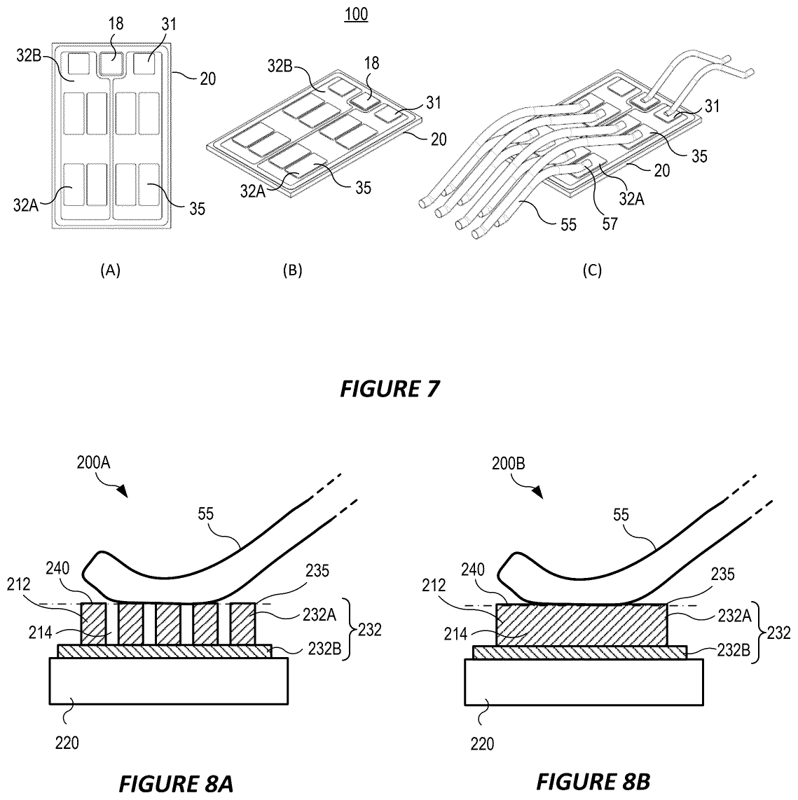

FIG. 7 depicts an example topside pattern for wire bonding in a device 100B including a plurality of bond pads 35 on a thin metal layer 32B that provides source contacts for the device 100B. The bond pads 35 may be square, rectangular or any other shape as desired to provide sufficient room for a wire bond foot 57 of a wire bond 55 that is connected to the bond pad 35. In the device 100B, the bond pads 35 are formed in pairs and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and directly away from the gate pad 18.

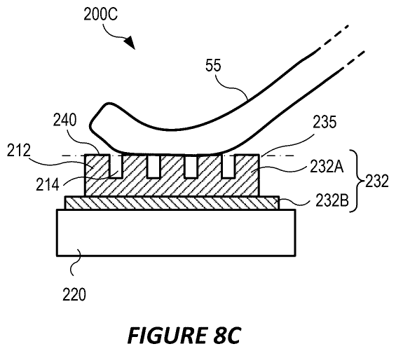

FIG. 8A illustrates a metal stack for a bond pad having a discontinuous upper surface according to some embodiments. Referring to FIG. 8A, a semiconductor device 200A according to some embodiments is illustrated. The semiconductor device 200A includes a semiconductor die 220 and a topside metallization 232 on the semiconductor die 221. The topside metallization 232 includes a bond pad 235 on a first side of the semiconductor die 220 to which a bond wire 55 may be attached. The bond pad 235 has a discontinuous uppermost surface 240 opposite the semiconductor die 220. The discontinuous uppermost surface 240 is provided by having a bond pad 235 that includes a discontinuous, i.e., non-continuous, layer of metal as the top metal layer of the bond pad 235.

To provide the discontinuous uppermost surface 240 opposite the semiconductor die 220, the bond pad 235 may be formed of a plurality of separated pillars 212. That is, the second metal layer 232A that forms the bond pad 235 is not a single continuous layer of metal, but is made up of multiple discrete metal regions in the form of pillars 212 that are separated by gaps, or holes (or openings) 214, therethrough.

At least one of the plurality of separated pillars 212 may have a width in a first direction that is less than a width of a footprint 237 of the bond wire 55 in the first direction, so that the bond wire 55 contacts multiple ones of the pillars 212 in a single bond pad 235. The top surfaces of the pillars 212 correspond to the discontinuous uppermost surface 240 of the bond pad 235 opposite the semiconductor die 220.

Alternatively or additionally, the bond pad 235 may be formed as a continuous layer having a plurality of holes 214 therein.

The bond pad 235 may be sized to receive a single wire bond 55, and may be formed from copper, aluminum and/or aluminum copper.

As noted above, the bond pad 235 may include a first metal layer 232B on the semiconductor die 220 and a second metal layer 232A on the first metal layer. The first metal layer 232B may have a first thickness, and the second metal layer 232A may have a second thickness. The second thickness may be larger than the first thickness. The first metal layer 232B and/or the second metal layer 232A may be formed from copper, aluminum and/or aluminum copper. The first metal layer 232B may be a continuous metal layer and the second metal layer 232A may be a discontinuous metal layer. That is, in some embodiments, the pillar/hole structure may not extend into the first metal layer 232B.

The semiconductor device 200 may further include a bond wire 55 that is bonded to the bond pad 235. The bond wire 55 contacts multiple ones of the plurality of pillars 212.

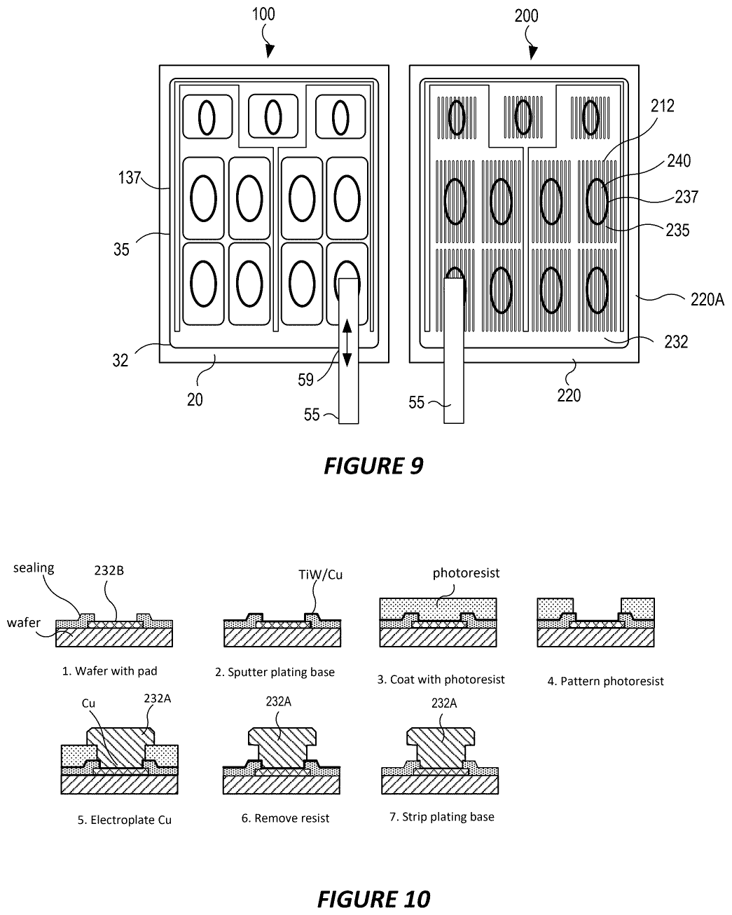

Brief reference is made to FIG. 9, which illustrates a conventional semiconductor device 100 and a semiconductor device 200 according to some embodiments. The conventional semiconductor device 100 includes a semiconductor substrate 20 on which a topside metallization 32 is formed. The topside metallization 32 includes a plurality of bond pads 35, each of which has a bonding area 36 on which a bond wire 55 may be attached, for example, using thermosonic scrub bonding. In thermosonic scrub bonding, the tip of a wire to be bonded is pressed against a bond pad, and both thermal (heat) and sonic (vibrational) energy are applied to the tip of the wire, causing it to metallurgically bond to the bond pad. The vibrational energy may be applied along a linear direction 59 parallel to the bond wire.

The semiconductor device 200 includes a semiconductor substrate 220 having an upper surface 220A. A topside metallization 232 is formed on the upper surface 220A of the substrate 220. The topside metallization 232 includes a plurality of bond pads 235 including a plurality of separate pillars 212 that form a discontinuous bonding surface 240. In the device 200, the pillars 212 are formed as elongated stripes that extend in a first direction that is parallel to the vibrational direction 59 used for thermosonic scrub bonding.

Each bond pad has a bonding area 237 on which a bond wire 55 may be attached.

As shown in FIG. 9, the bond wire footprint 237 spans multiple ones of the pillars 212, so that when the bond wire 55 is attached, the bond wire 55 will contact multiple ones of the pillars 212.

Referring again to FIG. 8A, the bond pad 235 may be a source bond pad, an emitter bond pad, an anode bond pad, a gate bond pad, a kelvin bond pad, or a signal bond pad.

FIG. 8B illustrates a semiconductor device 200B, which is similar to the device 200A shown in FIG. 8A, except that in the semiconductor device 200B, the pillars 212 run parallel to the direction in which the bond wire 55 extends. That is, in the configuration shown in FIG. 8A, the pillars 212 run perpendicular to the bond wire footprint, while in FIG. 8B, the pillars run parallel to the bond wire footprint.

FIG. 8C illustrates a semiconductor device 200B, which is similar to the device 200A shown in FIG. 8A, except that the holes 214 do not extend completely through the second metal layer 232A. Nevertheless, the bond pad 235 has a discontinuous uppermost surface 240.

FIG. 10 illustrates process steps that can be used to form the bond pad 235. In particular, a wafer is provided on which a first metal layer 232B is formed as a metal pad. A sealing layer is formed over the wafer, and an opening is made in the sealing layer to expose a portion of the lower metal layer (step 1). The first metal 232B may be, for example, Al, Cu, Al/Cu, etc. In step 2, a plating base of a metal such as TiW/Cu may optionally be sputtered onto the exposed portion of the first metal layer 232B. In step 3, the wafer is coated with a photoresist material, and in step 4, the photoresist material is patterned to expose the first metal layer 232B.

In step 5, the first metal layer 232B is plated with a metal, such as Al, Cu or Al/Cu to form the second metal layer 232A. The photoresist material is then removed in step 6, and the plating base, if present, is stripped in step 7.

The plurality of pillars 212 may have a peripheral shape, when viewed from a direction opposite the semiconductor die 220, that is in a shape of a stripe, a circle, a polygon, a ring, or other geometric shape.

In some embodiments, the plurality of holes 214 may have a peripheral shape, when viewed from a direction opposite the semiconductor die, that is in a shape of a stripe, a circle, a polygon, a ring or other geometric shape.

The pillars 212 may be oriented in a pattern of rows and columns. In some embodiments, the pillars may be oriented in a pattern of diagonals, crosses and/or in a chevron pattern.

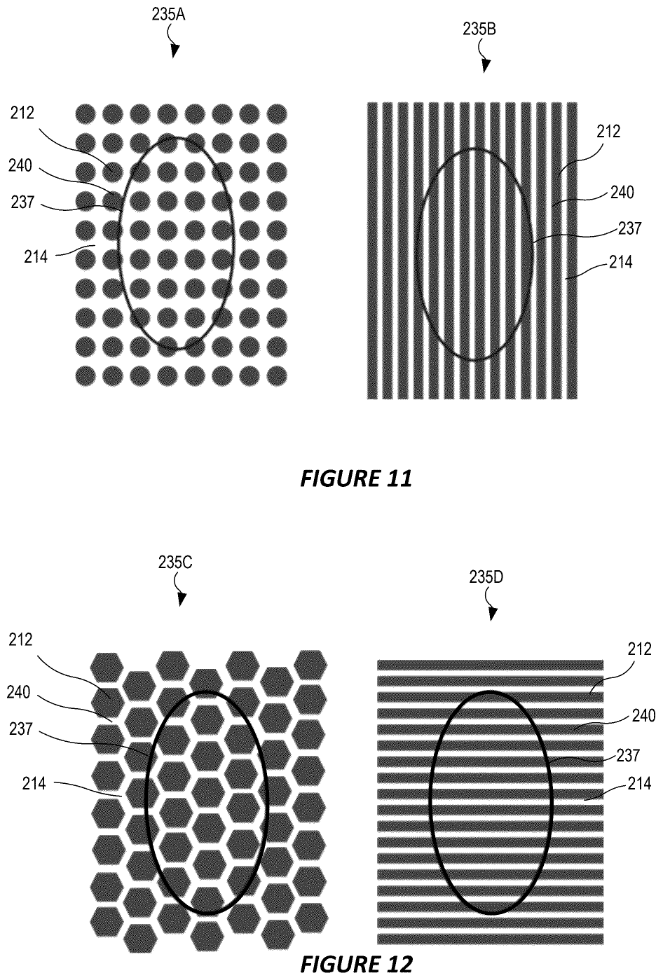

FIGS. 11-18 illustrate some possible configurations of the pillars 212 and holes 214 are provided according to various embodiments. For example, FIG. 11 illustrates a bond pad 235A in which the pillars 212 have a circular cross-sectional shape. The pillars 212 may have other geometric shapes, such as squares, hexagons, pentagons, polygonal, rhombohedral, etc. FIG. 11 also illustrates a bond pad 235B in which the pillars 212 and holes 214 have a striped cross-sectional shape oriented along the same direction as the vibrational direction along which a bond wire is attached using thermosonic scrub bonding.

FIG. 12 illustrates a bond pad 235C in which the pillars 212 have a hexagonal cross-sectional shape and a bond pad 235D in which the pillars and holes 214 have a striped cross-sectional shape oriented in a direction that is perpendicular to the direction of vibrational direction along which a bond wire is attached using thermosonic scrub bonding.

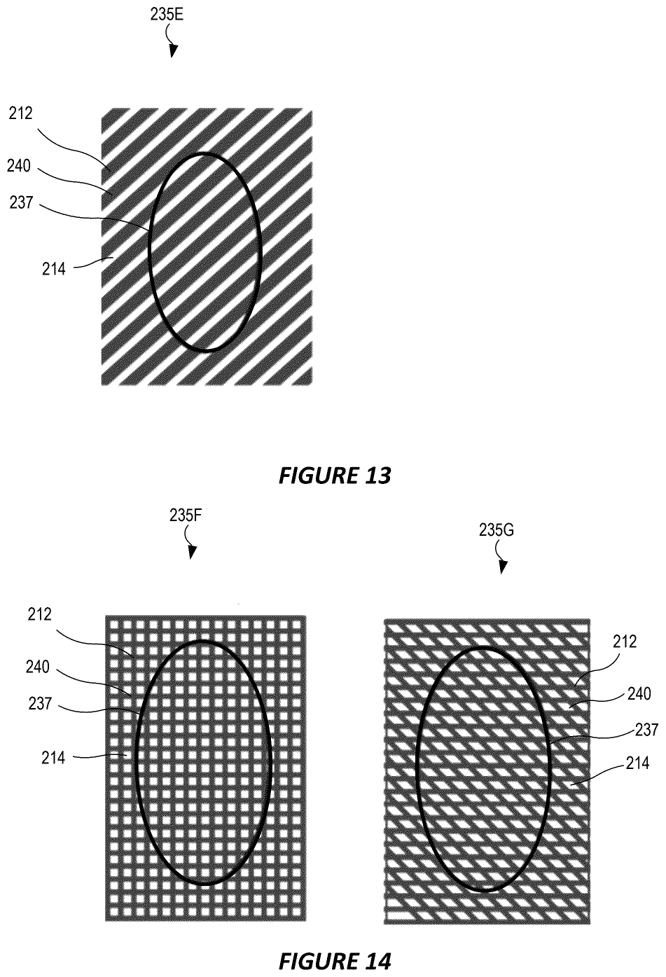

FIG. 13 illustrates a bond pad 235E in which the pillars and holes 214 have a striped cross-sectional shape oriented in a direction that is oblique to the direction of vibrational direction along which a bond wire is attached using thermosonic scrub bonding.

FIG. 14 illustrates a bond pad 235F in which the holes 214 have a square cross-sectional shape. The holes 214 may have other geometric shapes, such as squares, hexagons, pentagons, polygonal, rhombohedral, etc. FIG. 14 also illustrates a bond pad 235G in which the holes 214 have a rhombohedral cross-sectional shape.

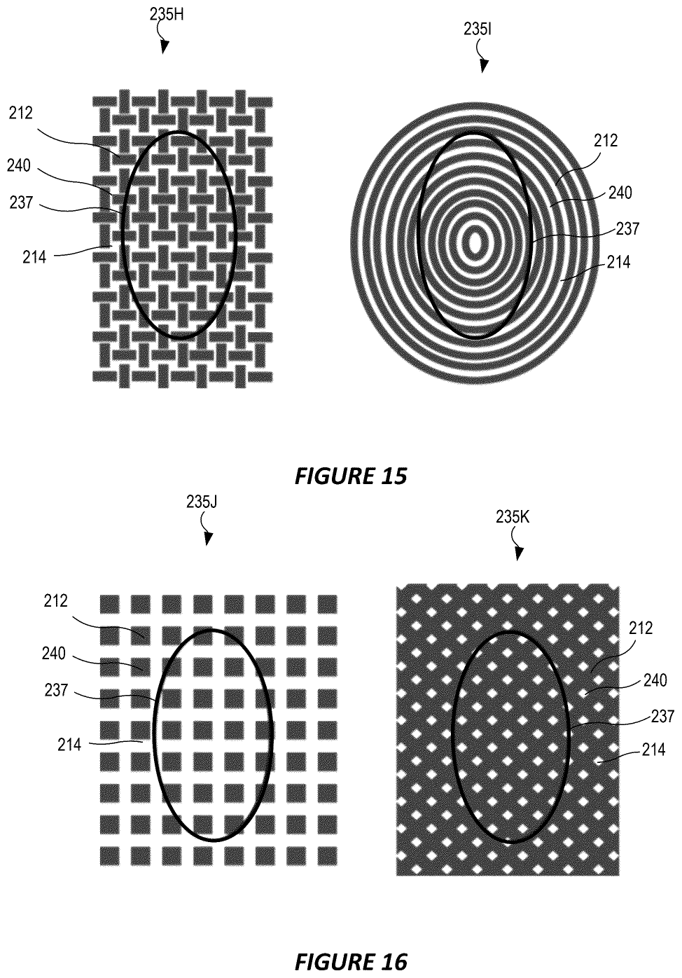

FIG. 15 illustrates a bond pad 235H in which the pillars 212 have a thatched or woven cross-sectional shape, and a bond pad 235I in which the holes 214 have a ring or curved cross-sectional shape.

FIG. 16 illustrates a bond pad 235J in which the pillars 212 have a square cross-sectional shape so that the holes 214 form a mesh shape, and a bond pad 235K in which the holes 214 have a diamond cross-sectional shape, so that the pillars 212 form a mesh shape.

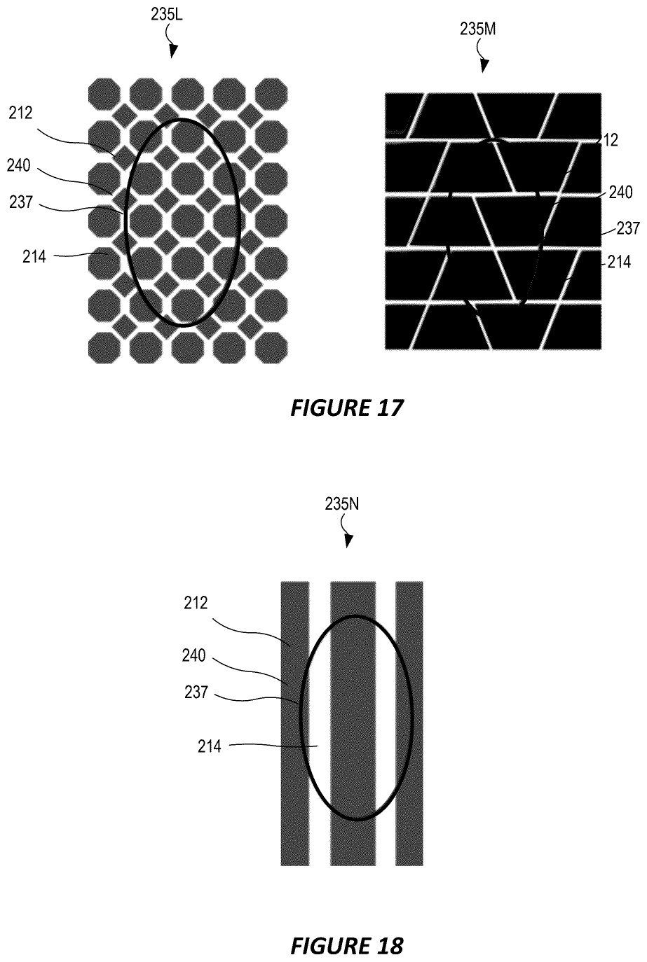

FIG. 17 illustrates a bond pad 235L in which the pillars 212 have different cross-sectional shapes. For example, some of the pillars 212 in the bond pad 235L have an octagonal cross-sectional shape, while others have a diamond square cross-sectional shape. FIG. 17 also illustrates a bond pad 235M in which the pillars 212 have a trapezoidal cross-sectional shape.

FIG. 18 illustrates a bond pad 200N in which the pillars 212 and holes 214 are provided as stripes having different widths. For example, in the bond pad 200N, the pillars 212 have larger widths than the holes 214.

While the above-described power semiconductor devices and the other devices described herein are shown as being silicon carbide-based semiconductor devices, it will be appreciated that embodiments of the present inventive concepts are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The inventive concepts have been described above with reference to the accompanying drawings, in which embodiments of the inventive concepts are shown. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present inventive concepts.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the inventive concepts.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present inventive concepts may include additional and/or intervening layers, structures, or elements, and/or particular layers, structures, or elements may be deleted. Although a few exemplary embodiments of the inventive concepts have been described, those skilled in the art will readily appreciate that many modifications are possible in the exemplary embodiments without materially departing from the novel teachings and advantages of the inventive concepts. Accordingly, all such modifications are intended to be included within the scope of the inventive concepts as defined in the claims. Therefore, it is to be understood that the foregoing is illustrative of the present inventive concepts and is not to be construed as limited to the specific embodiments disclosed, and that modifications to the disclosed embodiments, as well as other embodiments, are intended to be included within the scope of the appended claims. The inventive concepts are defined by the following claims, with equivalents of the claims to be included therein.

1. A semiconductor device, comprising:
a semiconductor die; and
a bond pad on a first side of the semiconductor die for receiving a wire bond, wherein the bond pad comprises a discontinuous uppermost surface opposite the first side of the semiconductor die.

2. The semiconductor device of claim 1, wherein the bond pad comprises a plurality of separated pillars.

3. The semiconductor device of claim 2, wherein at least one of the plurality of separated pillars has a width in a first direction that is less than a width of a footprint of the wire bond in the first direction.

4. The semiconductor device of claim 2, wherein the plurality of pillars have a peripheral shape, when viewed from a direction opposite the semiconductor die, that is in a shape of a stripe, a circle, a polygon, and/or a ring.

5. The semiconductor device of claim 1, wherein the bond pad comprises a continuous layer having a plurality of holes therein.

6. The semiconductor device of claim 5, wherein the plurality of holes have a peripheral shape, when viewed from a direction opposite the semiconductor die, that is in a shape of a stripe, a circle, a polygon, and/or a ring.

7. The semiconductor device of claim 1, wherein the bond pad is sized to receive a single wire bond.

8. The semiconductor device of claim 2, further comprising a bond wire that is bonded to the bond pad, wherein the bond wire contacts multiple ones of the plurality of pillars.

9. The semiconductor device of claim 1, wherein the bond pad comprises a first metal layer on the semiconductor die, the first metal layer having a first thickness, and a second metal layer on the first metal layer, the second metal layer having a second thickness.

10. The semiconductor device of claim 9, wherein the first metal layer comprises a continuous metal layer and the second metal layer comprises a discontinuous metal layer.

11. The semiconductor device of claim 1, wherein the bond pad comprises a source bond pad, an emitter bond pad, an anode bond pad, a gate bond pad, a kelvin bond pad, or a signal bond pad.

12. The semiconductor device of claim 2, wherein the pillars are oriented in a pattern of rows and columns.

13. The semiconductor device of claim 2, wherein the pillars are oriented in a pattern of diagonals, crosses and/or in a chevron pattern.

14. The semiconductor device of claim 1, wherein the bond pad comprises copper, aluminum and/or aluminum-copper.

15. A semiconductor device, comprising:
a semiconductor die; and
a bond pad on a first side of the semiconductor die for receiving a wire bond, wherein the bond pad comprises a plurality of separated pillars opposite the semiconductor die that are configured to receive a wire bond.

16. The semiconductor device of claim 15, wherein the plurality of separated pillars form a discontinuous uppermost surface opposite the semiconductor die.

17. The semiconductor device of claim 15, wherein at least one of the plurality of separated pillars has a width in a first direction that is less than a width of a footprint of the wire bond in the first direction.

18. The semiconductor device of claim 15, wherein the plurality of pillars have a peripheral shape, when viewed from a direction opposite the semiconductor die, that is in a shape of a stripe, a circle, a polygon, and/or a ring.

19. The semiconductor device of claim 15, wherein the bond pad comprises a continuous layer having a plurality of holes therein.

20. The semiconductor device of claim 19, wherein the plurality of holes have a peripheral shape, when viewed from a direction opposite the semiconductor die, that is in a shape of a stripe, a circle, a polygon, and/or a ring.

21. The semiconductor device of claim 15, wherein the bond pad is sized to receive a single wire bond.

22. The semiconductor device of claim 2, further comprising a bond wire that is bonded to the bond pad, wherein the bond wire contacts multiple ones of the plurality of pillars.

23. A semiconductor device, comprising:
a semiconductor die; and
a bond pad on a first side of the semiconductor die for receiving a wire bond, wherein the bond pad comprises a first metal layer on the semiconductor die and a second metal layer on the first metal layer, wherein the second metal layer has a discontinuous uppermost surface opposite the semiconductor die.

24. The semiconductor device of claim 23, wherein the second metal layer comprises a plurality of separated pillars opposite the semiconductor die.

25. Th semiconductor device of claim 24, wherein upper surfaces of the plurality of separated pillars form the discontinuous uppermost surface opposite the semiconductor die.

26. The semiconductor device of claim 23, wherein the first metal layer has a first thickness, and the second metal layer has a second thickness that is greater than the first thickness.

27. The semiconductor device of claim 26, wherein the first metal layer comprises a continuous metal layer and the second metal layer comprises a discontinuous metal layer.

28. The semiconductor device of claim 23, wherein the bond pad comprises a source bond pad, an emitter bond pad, an anode bond pad, a gate bond pad, a kelvin bond pad, or a signal bond pad.

29. The semiconductor device of claim 23, wherein the pillars are oriented in a pattern of rows and columns.

30. The semiconductor device of claim 24, wherein the plurality of separated pillars are oriented in a pattern of diagonals, crosses and/or in a chevron pattern.

31. The semiconductor device of claim 23, wherein the bond pad comprises copper, aluminum and/or aluminum-copper.

32. The semiconductor device of claim 23, wherein the second metal layer comprises a plurality of holes that extend partially through the second metal layer.
